(19) United States
(12) Patent Application Publication
(10) Pub. No.: US 2026/0045871 A1
(43) Pub. Date: Feb. 12, 2026

(54) FEEDFORWARD CIRCUITRY SYSTEM FOR DIRECT AC-COUPLING AND METHOD FOR REGULATING VOLTAGE USING THEREOF

(71) Applicant: SKYECHIP SDN BHD, BAYAN LEPAS (MY)

(72) Inventor: Hoong Chin NG, BAYAN LEPAS (MY)

(73) Assignee: SKYECHIP SDN BHD, BAYAN LEPAS (MY)

(21) Appl. No.: 19/070,683

(22) Filed: Mar. 5, 2025

(30) Foreign Application Priority Data
Aug. 8, 2024 (MY) PI2024004618

(51) Int. Cl. H02M 3/155; H03F 3/04

(52) U.S. Cl. CPC H02M 3/155; H03F 3/04

(57) ABSTRACT

A feedforward circuitry system for regulating voltage includes a voltage regulator for generating a regulated voltage, a bias generator operatively connected to the voltage regulator for generating a sub-threshold gate bias, a plurality of coupling capacitors, at least one of the coupling capacitors operatively connected to the bias generator for reading the sub-threshold gate bias and a feedforward amplifier operatively coupled with at least one of the coupling capacitors, characterized in that the plurality of coupling capacitors being configured to direct AC-couple an output transition of CMOS logic gates. A method for regulating voltage in a feedforward circuitry system through a direct AC-coupling is also provided.

### FIELD OF INVENTION

The present invention relates to a feedforward circuitry system used in voltage regulators. In particular, the present invention provides a zero latency feedforward circuitry by direct AC-coupling the input signal to the feedforward amplifier.

### BACKGROUND ART

Voltage regulation is one of the important aspects in electrical and electronic circuit design, providing particularly stable power levels in sensitive electronic devices or components. Its main function is to ensure that circuits receive a consistent voltage supply, regardless of fluctuations in input sources or changes in load conditions. This stability is crucial for the proper functioning of electronic components, preventing damage from overvoltage or undervoltage. Voltage regulation is known across the industries, from consumer electronics to industrial automation, telecommunications, and more. As technology continues to advance, the demand for efficient and precise voltage regulation solutions remains essential, resulting in ongoing innovation in this field.

Feedforward circuitry in voltage regulation also plays a role in enhancing the response time and its efficiency. By utilizing AC coupling, the need for complex level-shifting techniques and separate control logic is reduced, simplifying circuit design and reducing latency. This innovation enables voltage regulators to swiftly adapt to changes in current demands, thus improving their effectiveness in dynamic circuit environments.

Conventionally, voltage regulation has been adopted in various ways, including the use of charge pumps or switch capacitors. These methods take a current input or output from a regulated voltage rail depending on the circuit function. However, a disadvantage of these methods is that connecting a charge pump or switched capacitor requires a level-shift of the input signal to the unregulated voltage rail that includes the circuitry necessary for these components to locate extra area, power, complexity and latency.

Numerous breakthroughs have been made in addressing the limitations of conventional voltage regulation techniques. For example, the use of toggle detectors has been explored. These detectors are used to detect the activity of the input signal and then level-shifted to control the feed-forward amplifier. The feedforward amplifier then adjusts the current from or into the regulated voltage rail based on the output of the toggle detector. However, this method also faces challenges, especially with random patterns of singular toggling pulses due to the limitation of toggle detector.

One example of voltage regulator with feedforward circuitry is U.S. Pat. No. 10,185,339B2 that discloses a voltage regulator with feedforward cancellation of power supply noise utilizing a process tracking circuit and tracking capacitor. The tracking capacitor is coupled to the process tracking circuit, generates an injection voltage proportional to the voltage. This process is utilized within an Ahuja compensated regulator to produce a regulated voltage.

Another example is KR102596255B1 that discloses the mitigation of power voltage noise through a capacitive feedforward ripple cancellation circuit. The voltage regulator incorporates a capacitive feed-forward ripple cancellation circuit comprising a pass unit designed to relay an input voltage from an input terminal to an output voltage at an output terminal in response to a control signal. Furthermore, a capacitive feed-forward ripple cancellation unit is tasked with eliminating ripple from the input voltage by utilizing the reference voltage and the comparison signal, thereby generating the control signal.

A further example is CN117452998A that discloses PMOS power tube LDO circuit with feedforward zero-point stability compensation, primarily aimed at stability without relying on parasitic equivalent series resistance of a capacitor. It generates a zero point of a middle frequency band at a middle and high frequency through the feedforward circuit, and the zero point compensates phase roll-off caused by an LDO pole.

As outlined above, various feedforward circuitry has been developed in voltage regulators system. However, none of the prior arts disclose a system operating in dual modes for regulating both supply and ground voltage, nor do they detail a stability assurance mechanism by compensating for current variations caused by abrupt toggling activity.

### SUMMARY OF INVENTION

The present invention relates to a feedforward circuitry system used in voltage regulators. In particular, the present invention provides zero latency feedforward circuitry by direct AC-coupling of the input signal to the feedforward amplifier.

One aspect of the present invention provides a feedforward circuitry system for regulating voltage, comprising a voltage regulator for generating a regulated voltage; a bias generator operatively connected to the voltage regulator for generating a sub-threshold gate bias; a plurality of coupling capacitors, at least one of the coupling capacitors operatively connected to the bias generator for reading the sub-threshold gate bias; and a feedforward amplifier operatively coupled with at least one of the coupling capacitors; characterized in that the plurality of coupling capacitors being configured to direct AC-couple an output transition of CMOS logic gates; wherein the output transition of CMOS logic gates is driven by a plurality of data signals onto the gate bias of the feedforward amplifier; wherein the feedforward amplifier acts upon the voltage differences between the gate bias of the feedforward amplifier and the sub-threshold gate bias of the bias generator for current injection or current discharge.

Another aspect of the present invention provides that the plurality of coupling capacitors includes at least one main coupling capacitor and at least one programmable capacitor being configured to cover Process-Voltage-Temperature variation.

Yet another aspect of the present invention provides that the feedforward amplifier comprises at least one NMOS or PMOS in common-drain amplifier configuration, and a resistance resistor.

Yet another aspect of the present invention provides that the bias generator comprises a resistance resistor, a NMOS or PMOS in diode connection and a capacitor.

Another aspect of the present invention provides that a method for regulating voltage in a feedforward circuitry system through a direct AC-coupling, the method comprising the steps of regulating voltage according to an input reference voltage from a bandgap or a resistor ladder; generating a sub-threshold gate bias by a bias generator; characterized by AC-coupling an output transition of CMOS logic gates by a plurality of coupling capacitors based on a plurality of data signals onto a gate bias of a feedforward amplifier; wherein the feedforward amplifier acts upon the voltage differences between the gate bias of the feedforward amplifier and the sub-threshold gate bias of the bias generator for current injection or current discharge.

Yet another aspect of the present invention provides that the method for regulating supply voltage comprising the steps of regulating supply voltage according to an input reference voltage from a bandgap or a resistor ladder; generating a sub-threshold gate bias by a bias generator; identifying voltage differences between the gate bias of a feedforward amplifier and the sub-threshold gate bias of the bias generator; wherein disabling the feedforward amplifier when the voltage level of the gate bias is equal to the sub-threshold gate bias that leads to a static data signal; wherein AC-coupling an output transition of CMOS logic gates by a plurality of coupling capacitors when the voltage level of the gate bias is above the sub-threshold gate bias that leads to a toggling data signal, and injecting current into the regulated supply voltage from a positive supply voltage connection by the feedforward amplifier.

Yet another aspect of the present invention that the method for regulating ground voltage comprising the steps of regulating ground voltage according to an input reference voltage from a bandgap or a resistor ladder; generating a sub-threshold gate bias by a bias generator; identifying voltage differences between the gate bias of a feedforward amplifier and the sub-threshold gate bias of the bias generator; wherein disabling the feedforward amplifier when the voltage level of the gate bias is equal to the sub-threshold gate bias that leads to a static data signal; wherein AC-coupling an output transition of CMOS logic gates by a plurality of coupling capacitors when the voltage level of the gate bias is below the sub-threshold gate bias that leads to a toggling data signal, and sinking current from the regulated ground voltage into ground supply voltage connection by the feedforward amplifier.

Another aspect of the present invention provides that the output transition of CMOS logic gates is controlled by at least one programmable capacitor driven by a NAND gate with an active-high enable.

Yet another aspect of the present invention provides that the output transitions of CMOS logic gates is controlled by at least one programmable capacitor driven by a NOR gate with an active-low enable.

The present invention consists of features and a combination of parts hereinafter fully described and illustrated in the accompanying drawings, it being understood that various changes in the details may be made without departing from the scope of the invention or sacrificing any of the advantages of the present invention.

### BRIEF DESCRIPTION OF ACCOMPANYING DRAWINGS

To further clarify various aspects of some embodiments of the present invention, a more particular description of the invention will be rendered by references to specific embodiments thereof, which are illustrated in the appended drawings. It is appreciated that these drawings depict only typical embodiments of the invention and are therefore not to be considered limiting of its scope. The invention will be described and explained with additional specificity and detail through the accompanying drawings in which:

FIG. 1 shows a block diagram of a feedforward circuitry system in the form of regulating supply voltage in accordance with an embodiment of the present invention;

FIG. 2 depicts waveforms of data signals including static and toggle waveforms, and current injection in regulating supply voltage;

FIG. 3 shows a block diagram of the feedforward circuitry system in the form of regulating ground voltage in accordance with an embodiment of the present invention; and

FIG. 4 depicts waveforms of data signals including static and toggle waveforms, and current discharge in regulating ground voltage.

### DETAILED DESCRIPTION OF THE PREFERRED EMBODIMENTS

While the present invention is described herein by way of example using embodiments and illustrative drawings, those skilled in the art will recognize that the invention is not limited to the embodiments of drawing or drawings described and are not intended to represent the scale of the various components. Further, some components that may form a part of the invention may not be illustrated in certain figures, for ease of illustration, and such omissions do not limit the embodiments outlined in any way. It should be understood that the drawings and detailed description thereto are not intended to limit the invention to the particular form disclosed, but on the contrary, the invention is to cover all modifications, equivalents, and alternatives falling within the scope of the present invention as defined by the appended claim. As used throughout this description, the word “may” is used in a permissive sense (i.e. meaning having the potential to), rather than the mandatory sense, (i.e. meaning must). Further, the words “a” or “an” mean “at least one” and the word “plurality” means “one or more” unless otherwise mentioned. Furthermore, the terminology and phraseology used herein is solely for descriptive purposes and should not be construed as limiting in scope. Language such as “including,” “comprising,” “having,” “containing,” or “involving,” and variations thereof, is intended to be broad and encompass the subject matter listed thereafter, equivalents, and additional subject matter not recited, and is not intended to exclude other additives, components, integers or steps. Likewise, the term “comprising” is considered synonymous with the terms “including” or “containing” for applicable legal purposes. Any discussion of documents, acts, materials, devices, articles and the like is included in the specification solely to provide a context for the present invention. It is not suggested or represented that any or all of these matters form part of the prior art base or were common general knowledge in the field relevant to the present invention.

In this disclosure, whenever a composition or an element or a group of elements is preceded with the transitional phrase “comprising”, it is understood that we also contemplate the same composition, element or group of elements with transitional phrases “consisting of”, “consisting”, “selected from the group of consisting of, “including”, or “is” preceding the recitation of the composition, element or group of elements and vice versa.

The present invention is described hereinafter by various embodiments. This invention may, however, be embodied in many different forms and should not be construed as limited to the embodiment set forth herein. Rather, the embodiment is provided so that this disclosure will be thorough and complete and will fully convey the scope of the invention to those skilled in the art. In the following detailed description, numeric values and ranges are provided for various aspects of the implementations described. These values and ranges are to be treated as examples only and are not intended to limit the scope of the claims. In addition, several materials are identified as suitable for various facets of the implementations. These materials are to be treated as exemplary and are not intended to limit the scope of the invention.

The present invention relates to a feedforward circuitry system (1) used in voltage regulators. In particular, the present invention provides zero latency feedforward circuitry by direct AC-coupling the input signal to the feedforward amplifier.

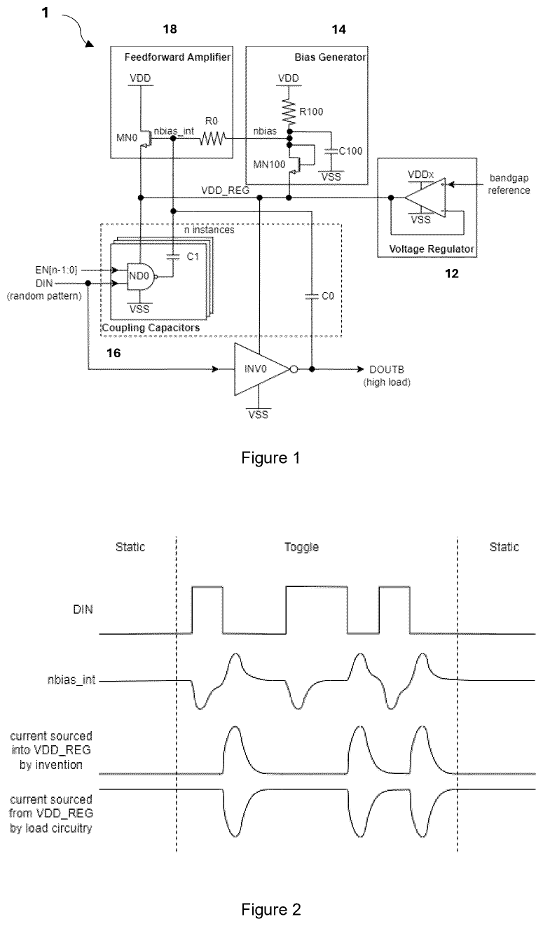

Referring to FIGS. 1 and 4, the invention will now describe in more details. The figures show the exemplary block diagrams and waveforms in the form of regulating supply voltage and regulating ground voltage respectively. It is understandable by a skilled person in the art that in actual implementation, the block diagram is not limited to the forms of regulating voltage, it can be very complex, the circuitry can be injecting current or discharging current from the regulated voltage-rail based on the toggling pattern.

The feedforward circuitry system (1) of the present invention comprising a voltage regulator (12), a bias generator (14), a plurality of the coupling capacitors (16) and a feedforward amplifier. The voltage regulator (12) generates a regulated voltage, a bias generator (14) operatively connected to the voltage regulator (12) for generating a sub-threshold gate bias, at least one of the plurality of coupling capacitors (16) operatively connected to the sub-threshold gate bias, and the feedforward amplifier operatively coupled with at least one of the coupling capacitors, characterized by the plurality of coupling capacitors (16) being configured to direct AC-couple an output transition of CMOS logic gates, wherein the output transition of CMOS logic gates is driven by a plurality of data signals, DIN, onto the gate bias of the feedforward amplifier (18), wherein the feedforward amplifier (18) acts upon the voltage differences between the gate bias of the feedforward amplifier (18) and the sub-threshold gate bias of the bias generator (14) for current injection or current discharge.

FIG. 1 is the block diagram of the feedforward circuitry in the form of regulating supply voltage. The voltage regulator (12) generates the regulated supply voltage, VDD_REG, based on an input reference voltage. Then, the bias generator (14) generates the sub-threshold gate bias, nbias, to the feedforward amplifier (18). Further, the coupling capacitors AC-couples the output transitions of CMOS logic gates that are driven by the data signal, DIN onto the gate bias of the feedforward amplifier (18). Lastly, the feedforward amplifier (18) injects current into the regulated supply voltage, VDD_REG from VDD based on the activity of the data signal, DIN.

In accordance with an embodiment of the present invention, the voltage regulator (12) generates the regulated supply voltage, the input reference voltage can be from either a bandgap or a resistor ladder.

In accordance with an embodiment of the present invention, the bias generator (14) generates the sub-threshold gate bias, nbias to the feedforward amplifier (18), a high resistance resistor, R100 along with a large NMOS in diode connection, MN100 are utilized to obtain a bias that is slightly lower than VDD_REG+Vt_{MN0}. Vt_{MN0} is the threshold voltage of MNO in the feedforward amplifier (18). Alternatively, the large NMOS in diode connection can be replaced with a diode. Additionally, a large capacitor, C100 is connected to the nbias to stabilize its voltage level. Optionally, a unity-gain buffer may be incorporated onto the nbias for the same purpose.

In accordance with an embodiment of the present invention and in reference to FIG. 1, the coupling capacitors AC-couples the output transitions of CMOS logic gates, a C0 capacitor serves as the main coupling capacitor, sized to meet the minimum capacitance requirements across all Process-Voltage-Temperature, PVT conditions. Conversely, the programmable C1 capacitors allow for precise adjustments to accommodate PVT variations. Each element within the array of programmable C1 capacitors is controlled by a NAND gate, ND0, featuring an active-high enable signal, EN. The selection of NAND gate is deliberate as its output remains high when disabled, thereby minimizing the voltage difference between the disabled C1 capacitors. This is crucial for reducing the effective parasitic capacitance on the gate bias of the feedforward amplifier (18). The C0 and C1 capacitors can be implemented using metal-oxide-metal, MOM capacitors, MOS capacitors, or a hybrid combination of MOM and MOS capacitors.

In accordance with an embodiment of the present invention, the feedforward amplifier (18) injects current into the regulated supply voltage. The feedforward amplifier (18) comprises an NMOS in a common-drain amplifier configuration, MN0, along with a high-resistance resistor, R0, to produce a weak DC gate bias, nbias_int, for MN0. With this weak DC bias and minimal parasitic net capacitance, the output transitions of CMOS logic gates driven by the data signal, DIN, can seamlessly AC-couple onto nbias_int through the coupling capacitors.

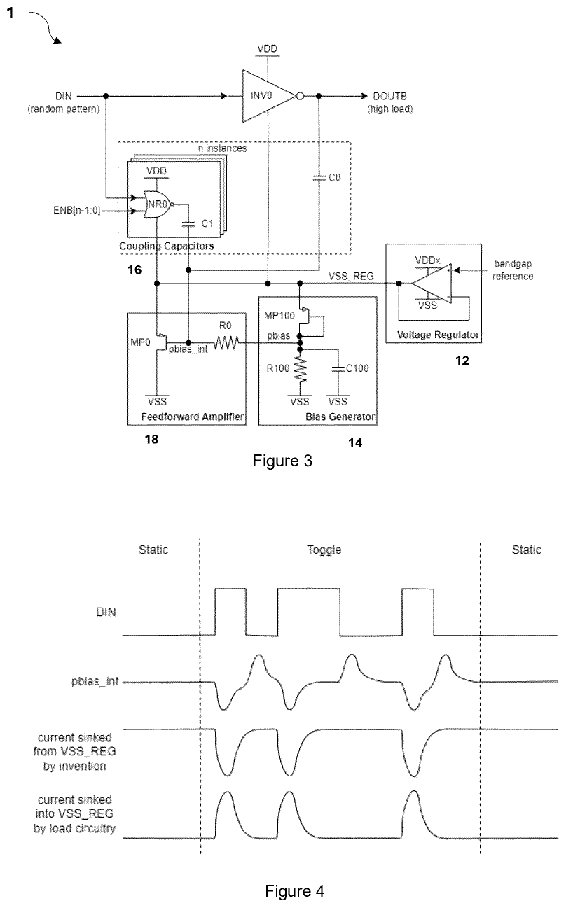

FIG. 3 is the block diagram of the feedforward circuitry in the form of regulating ground voltage. The voltage regulator (12) generates the regulated ground voltage, VSS_REG, based on an input reference voltage. Then, the bias generator (14) generates the sub-threshold gate bias, pbias to the feedforward amplifier (18). Further, the coupling capacitors AC-couples the output transitions of CMOS logic gates that are driven by the data signal, DIN onto the gate bias of the feedforward amplifier (18). Lastly, the feedforward amplifier (18) sinks current from the regulated supply voltage, VSS_REG from VSS based on the activity of the data signal, DIN.

In accordance with an embodiment of the present invention, the voltage regulator (12) generates the regulated ground voltage, the input reference voltage can be from either a bandgap or a resistor ladder.

In accordance with an embodiment of the present invention, wherein the bias generator (14) generates the sub-threshold gate bias, pbias to the feedforward amplifier (18), a high resistance resistor, R100 along with a large PMOS in diode connection, MP100 are utilized to obtain a bias that is slightly lower than VSS_REG+Vt_{MP0}. Vt_{MP0} is the threshold voltage of MP0 in the feedforward amplifier (18). Alternatively, the large NMOS in diode connection can be replaced with a diode. Additionally, a large capacitor, C100 is connected to the pbias to stabilize its voltage level. Optionally, a unity-gain buffer may be incorporated onto the pbias for the same purpose.

In accordance with an embodiment of the present invention, wherein the coupling capacitors AC-couples the output transitions of CMOS logic gates, a CO capacitor serves as the main coupling capacitor, sized to meet the minimum capacitance requirements across all Process-Voltage-Temperature, PVT conditions. Conversely, the programmable C1 capacitors allow for precise adjustments to accommodate PVT variations. Each element within the array of programmable C1 capacitors is controlled by a NOR gate, NR0, featuring an active-low enable signal, ENB. The selection of NOR gate is deliberate as its output remains low when disabled, thereby minimizing the voltage difference between the disabled C1 capacitors. This is crucial for reducing the effective parasitic capacitance on the gate bias of the feedforward amplifier (18). The C0 and C1 capacitors can be implemented using metal-oxide-metal, MOM capacitors, MOS capacitors, or a hybrid combination of MOM and MOS capacitors.

In accordance with an embodiment of the present invention, the feedforward amplifier (18) sinks current from the regulated ground voltage. The feedforward amplifier (18) comprises an PMOS in a common-drain amplifier configuration, MP0, along with a high-resistance resistor, R0, to produce a weak DC gate bias, pbias_int, for MP0. With this weak DC bias and minimal parasitic net capacitance, the output transitions of CMOS logic gates driven by the data signal, DIN, can seamlessly AC-couple onto pbias_int through the coupling capacitors.

The present invention also discloses a method for regulating voltage in the feedforward circuitry system (1) through the direct AC-coupling. The voltage includes supply voltage and ground voltage, wherein the AC-coupling takes place when data toggles in which current is injected into the regulated supply voltage for regulating supply voltage and current is sunk from the regulated ground voltage for regulating ground voltage.

Hereinafter, an example of the present invention will be provided for more detailed explanation by referring to FIGS. 2 and 4. The advantages of the present invention may be more readily understood and put into practical effect from this example. However, it is to be understood that the following example is not intended to limit the scope of the present invention in any ways.

### EXAMPLES

FIG. 2 depicts the signal waveforms in the form of regulating supply voltage. The signal waveforms describes when DIN remains static, the feedforward amplifier (18) is disable since DC gate bias, nbias_int is equal to the sub-threshold gate bias, nbias voltage level. However, when DIN toggles, the CMOS logic gates driven by DIN AC-couple nbias_int. Consequently, the feedforward amplifier (18) is enabled, injecting current into VDD_REG whenever nbias_int is higher the nbias voltage level. The current drawn from VDD_REG by the load circuitry is offset by the current injected into VDD_REG by the feedforward amplifier (18) through appropriate sizing and calibration of coupling capacitors. This results in the attainment of a stable VDD_REG, even with an abrupt toggling activity.

FIG. 4 depicts the signal waveforms in the form of regulating ground voltage. The signal waveforms describes when DIN remains static, the feedforward amplifier (18) is disable since DC gate bias, pbias_int is equal to the sub-threshold gate bias, pbias voltage level. However, when DIN toggles, the CMOS logic gates driven by DIN AC-couple the pbias_int. Consequently, the feedforward amplifier (18) is enabled, sinking current from VSS_REG whenever pbias_int is lower than the pbias voltage level. The current drawn from VSS_REG by the load circuitry is offset by the current sank from VSS_REG by the feedforward amplifier (18) through appropriate sizing and calibration of coupling capacitors. This results in the attainment of a stable VSS_REG, even with an abrupt toggling activity.

Various modifications to these embodiments are apparent to those skilled in the art from the description and the accompanying drawings. The principles associated with the various embodiments described herein may be applied to other embodiments. Therefore, the description is not intended to be limited to the embodiments shown along with the accompanying drawings but is to be providing broadest scope of consistent with the principles and the novel and inventive features disclosed or suggested herein. Accordingly, the invention is anticipated to hold on to all other such alternatives, modifications, and variations that fall within the scope of the present invention and appended claim.

1. A feedforward circuitry system for regulating voltage, comprising:
a voltage regulator for generating a regulated voltage;
a bias generator operatively connected to the voltage regulator for generating a sub-threshold gate bias;
a plurality of coupling capacitors, at least one of the coupling capacitors operatively connected to the bias generator for reading the sub-threshold gate bias; and
a feedforward amplifier operatively coupled with at least one of the coupling capacitors;
wherein the plurality of coupling capacitors being configured to direct AC-couple an output transition of CMOS logic gates;
wherein the output transition of CMOS logic gates is driven by a plurality of data signals onto the gate bias of the feedforward amplifier;
wherein the feedforward amplifier acts upon the voltage differences between the gate bias of the feedforward amplifier and the sub-threshold gate bias of the bias generator for current injection or current discharge.

2. The feedforward circuitry system according to claim 1, wherein the plurality of coupling capacitors includes at least one main coupling capacitor and at least one programmable capacitor being configured to cover Process-Voltage-Temperature variation.

3. The feedforward circuitry system according to claim 1, wherein the feedforward amplifier comprises at least one NMOS or PMOS in common-drain amplifier configuration, and a resistance resistor.

4. The feedforward circuitry system according to claim 1, wherein the bias generator comprises a resistance resistor, a NMOS or PMOS in diode connection and a capacitor.

5. A method for regulating voltage in a feedforward circuitry system through a direct AC-coupling, the method comprising:
regulating voltage according to an input reference voltage from a bandgap or a resistor ladder;
generating a sub-threshold gate bias by a bias generator;
characterized by
AC-coupling an output transition of CMOS logic gates by a plurality of coupling capacitors based on a plurality of data signals onto a gate bias of a feedforward amplifier;
wherein the feedforward amplifier acts upon the voltage differences between the gate bias of the feedforward amplifier and the sub-threshold gate bias of the bias generator for current injection or current discharge.

6. The method according to claim 5, wherein regulating supply voltage further comprises:
regulating supply voltage according to an input reference voltage from a bandgap or a resistor ladder;
generating a sub-threshold gate bias by a bias generator;
identifying voltage differences between the gate bias of a feedforward amplifier and the sub-threshold gate bias of the bias generator;
wherein disabling the feedforward amplifier when the voltage level of the gate bias is equal to the sub-threshold gate bias that leads to a static data signal;
wherein AC-coupling an output transition of CMOS logic gates by a plurality of coupling capacitors when the voltage level of the gate bias is above the sub-threshold gate bias that leads to a toggling data signal, and injecting current into the regulated supply voltage from a positive supply voltage connection by the feedforward amplifier.

7. The method according to claim 5, wherein regulating ground voltage further comprises:
regulating ground voltage according to an input reference voltage from a bandgap or a resistor ladder;
generating a sub-threshold gate bias by a bias generator;
identifying voltage differences between the gate bias of a feedforward amplifier and the sub-threshold gate bias of the bias generator;
wherein disabling the feedforward amplifier when the voltage level of the gate bias is equal to the sub-threshold gate bias that leads to a static data signal;
wherein AC-coupling an output transition of CMOS logic gates by a plurality of coupling capacitors when the voltage level of the gate bias is below the sub-threshold gate bias that leads to a toggling data signal, and sinking current from the regulated ground voltage into ground supply voltage connection by the feedforward amplifier.

8. The method according to claim 6, wherein AC coupling the output transition of CMOS logic gates is controlled by at least one programmable capacitor driven by a NAND gate with an active-high enable.

9. The method according to claim 7, wherein AC coupling the output transitions of CMOS logic gates is controlled by at least one programmable capacitor driven by a NOR gate with an active-low enable.
